(19) United States
(12) Patent Application Publication
(10) Pub. No.: US 2009/0288859 A1
(43) Pub. Date: Nov. 26, 2009

(54) NON-CYLINDER VIA STRUCTURE AND THERMAL ENHANCED SUBSTRATE HAVING THE SAME

(75) Inventors: Wen-Cheng Ho, Hsinchu (TW); Tzu-Shih Shen, Hsinchu (TW)

Correspondence Address: J C PATENTS, 4 VENTURE, SUITE 250, IRVINE, CA, 92618, US

(73) Assignee: SUBTRON TECHNOLOGY CO. LTD., Hsinchu (TW)

(21) Appl. No.: 12/401,064

(22) Filed: Mar. 10, 2009

(30) Foreign Application Priority Data
May 20, 2008 (TW) 97118548

(51) Int. Cl. H05K 7/20; H01B 5/00

(52) U.S. Cl. 174/252; 174/126.1

(57) ABSTRACT

A thermal enhanced substrate having a non-cylinder via structure includes at least a metal layer disposed on an insulating base material and a number of thermal channels respectively constituted by at least a trough pattern penetrating the insulating base material and a conductive material deposited in the trough pattern. The trough pattern serves as a non-cylinder via structure having at least an elongated hole for heat dissipations so as to reduce a working temperature of an electronic device.

### CROSS-REFERENCE TO RELATED APPLICATION

This application claims the priority benefit of Taiwan application serial no. 97118548, filed on May 20, 2008. The entirety of the above-mentioned patent application is hereby incorporated by reference herein and made a part of specification.

### BACKGROUND OF THE INVENTION

1. Field of the Invention

The present invention relates to a thermal enhanced substrate. More particularly, the present invention relates to a thermal enhance substrate having a non-cylinder via structure.

2. Description of Related Art

A light emitting diode (LED) is a light emitting device mainly formed by adjusting III-V or II-IV group compound semiconductor materials and the structure of the device. Since the operating principle and the structure of the LEDs are different from those of conventional tungsten bulbs, the LEDs have numerous advantages including compact volume, durability, low driving voltage, fast response speed and good shock resistance in comparison with the conventional tungsten bulbs which have disadvantages of high electricity consumption, high heat radiation, poor shock resistance, and short lifetime. Hence, the LEDs have been widely applied to various electronic products including portable communication products, traffic signs, outdoor billboards, illumination for vehicles, illuminators, and so forth.

Nevertheless, along with the development of the fabricating techniques, light emitting efficiency and luminance of the LEDs are gradually improved, thereby complying with requirements for all kinds of products and expanding applications of the LEDs. In other words, in order to increase the brightness of the LEDs, external package problems of the LEDs should be solved, and a design of the LEDs with high power and high working current is required as well, so as to manufacture the LEDs featuring satisfactory luminance. However, under the circumstance of increasing the power and the working current, the LEDs generate more heat, so the performance thereof is apt to be compromised by overheat; what is worse, overheat even causes malfunction of the LEDs.

FIG. 1 is a schematic view of a conventional thermal enhanced substrate. To improve heat dissipation capacity, a plurality of cylinder vias 130 penetrating a metal layer 110 that is located above the conventional thermal enhanced substrate 100 are often formed in an insulating base material 120. The cylinder vias 130 serve as heat dissipation holes. Besides, the cylinder vias 130 have a conductive material therein for respectively conducting and dissipating heat generated by a light emitting device (not shown) through the cylinder vias 130, so as to reduce a working temperature of the light emitting device.

Nonetheless, the vias 130 and the conductive material therein have the cylinder structures and individually perform the heat dissipation function. Thereby, capability of heat dissipation is confined, and the vias 130 can merely be applied to light emitting devices that generate less heat. As such, heat dissipation requirements of high power light emitting devices cannot be satisfied.

### SUMMARY OF THE INVENTION

The present invention is directed to a non-cylinder via structure and a thermal enhanced substrate having the same, so as to meet heat dissipation requirements of high power electronic devices.

In the present invention, a non-cylinder via structure suitable for being used in a thermal enhanced substrate is provided. The thermal enhance substrate supports an electronic device and has at least one metal layer and a plurality of thermal channels. The thermal channels respectively include at least one trough pattern penetrating the thermal enhance substrate and a conductive material deposited in the trough pattern. Here, the trough pattern serves as the non-cylinder via structure having at least one elongated hole.

In the present invention, a thermal enhanced substrate suitable for supporting an electronic device is also provided. The thermal enhance substrate includes at least one metal layer disposed on an insulating base material and a plurality of thermal channels. The thermal channels respectively include at least one trough pattern penetrating the insulating base material and a conductive material deposited in the trough pattern. Here, the trough pattern serves as a non-cylinder via structure having at least one elongated hole.

According to an embodiment of the present invention, the elongated hole is formed by ablating the thermal enhanced substrate with use of a plurality of continuous pulse waves. In addition, the elongated hole is formed by a plurality of cylinder vias arranged along a length direction of the elongated hole. On the other hand, two ends of the elongated hole along a length direction have a semicircular shape, for example.

According to an embodiment of the present invention, the trough pattern has a bar shape, a cross shape, an X shape, an Y shape, an T shape, an L shape, an U shape, an H shape, a [symbol] shape, or a combination of at least two said shapes.

According to an embodiment of the present invention, the conductive material is formed by performing an electroplating process, and the conductive material is copper, for example.

In the present invention, the non-cylinder via structure having the elongated hole is provided, and therefore the thermal channels occupy a relatively large heat dissipation area and have favorable heat dissipating efficiency, such that the heat dissipation requirements of the high power electronic devices can be satisfied.

In order to make the aforementioned and other features and advantages of the present invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic view of a conventional thermal enhanced substrate.

FIGS. 2A, 3, and 4A are schematic views respectively illustrating methods of fabricating a non-cylinder via structure and a thermal enhanced substrate having the non-cylinder via structure according to the present invention.

FIGS. 2B, 2C and 2D are top views respectively illustrating the non-cylinder via structure depicted in FIG. 2A according to three embodiments of the present invention.

FIGS. 4B and 4C are top views respectively illustrating a metal patterned layer depicted in FIG. 4A according to two embodiments of the present invention.

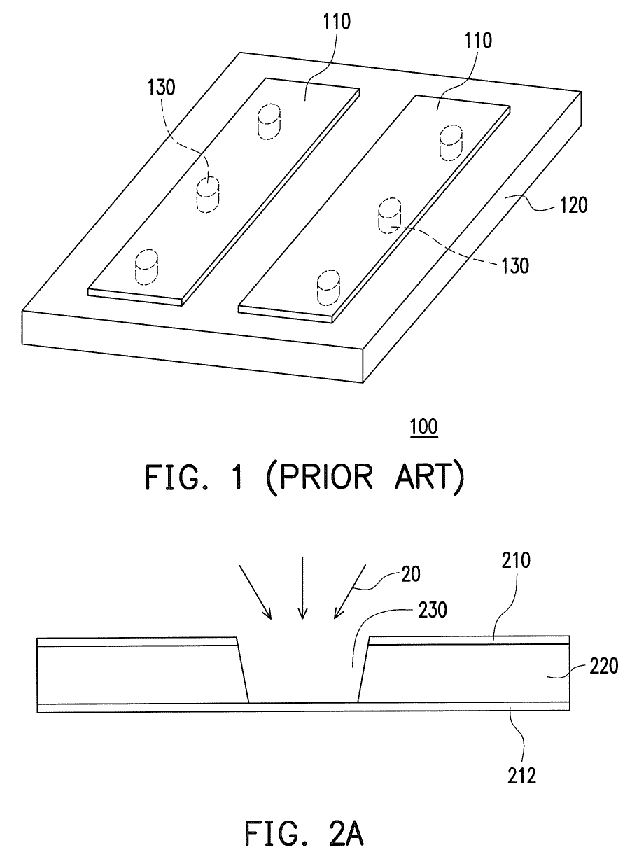

### DESCRIPTION OF EMBODIMENTS

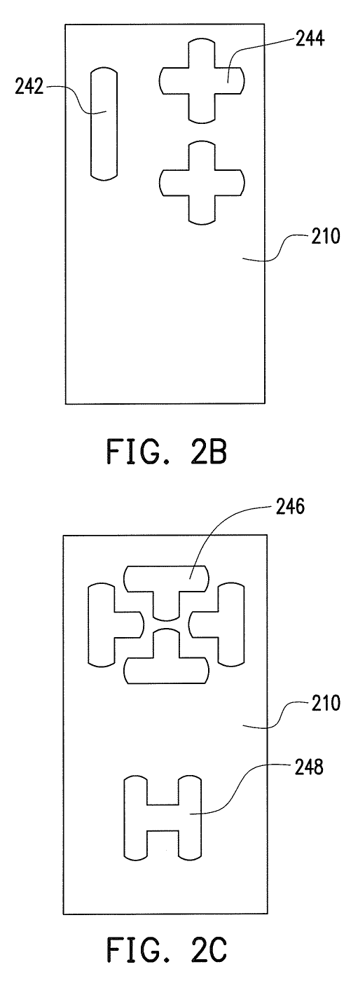

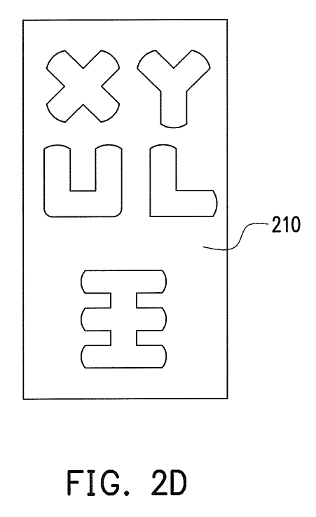

FIGS. 2A, 3, and 4A are schematic views respectively illustrating methods of fabricating a non-cylinder via structure and a thermal enhanced substrate having the non-cylinder via structure according to the present invention. In the present embodiment, a laser ablating technology is applied to form the non-cylinder via structure, which should not be construed as a limitation to the present invention. A photolithography technique and a chemical etching technique known to people skilled in the art can also be applied for forming the thermal enhanced substrate according to the present invention.

Referring to FIG. 2A, a metal layer 210 on an insulating base material 220 is ablated by laser, and at least a non-cylinder via structure 230 is formed in the insulating base material 220. The metal layer 210 is made of copper, for example. However, the metal layer 210 is not limited to one layer or more layers, which can be modified by the requirement of products. Besides, the insulating base material 220 is, for example, a polymer base material, such as epoxy resin, polyimide, or the like. When an excited laser beam 20 in a high energy state is applied to the metal layer 210, the non-cylinder via structure 230 having a predetermined depth and width can be formed. This is because a diameter of the laser beam 20 remains unchanged, and an etching depth and an etching speed of the laser beam 20 can be controlled. Therefore, in the present invention, a laser pick-up can be moved and advanced toward a predetermined direction, so as to emit continuous pulse waves and form the non-cylinder via structure 230 having at least an elongated hole. In other words, a plurality of cylinder vias formed by performing an etching process continuously and arranged along a length direction can together form an elongated hole. Thereby, the elongated hole has a length, and two ends of the elongated hole in the length direction form a pair of semicircles. Additionally, a width of the elongated hole is substantially equal to the diameter of the laser beam 20.

FIGS. 2B, 2C and 2D are top views respectively illustrating the non-cylinder via structure depicted in FIG. 2A according to three embodiments of the present invention. As shown in FIG. 2B, the trough pattern formed by the non-cylinder via structure 230 is composed of a bar-shaped pattern 242 and two cross-shaped patterns 244, for example. By contrast, as shown in FIG. 2C, the trough pattern formed by the non-cylinder via structure 230 is composed of four T-shaped patterns 246 and an H-shaped pattern 248, for example. Certainly, as shown in FIG. 2D, other trough patterns such as X-shaped patterns, Y-shaped patterns, L-shaped patterns, U-shaped patterns, [symbol] shaped patterns, or patterns having at least a combination of two said shapes are applicable in the present embodiment.

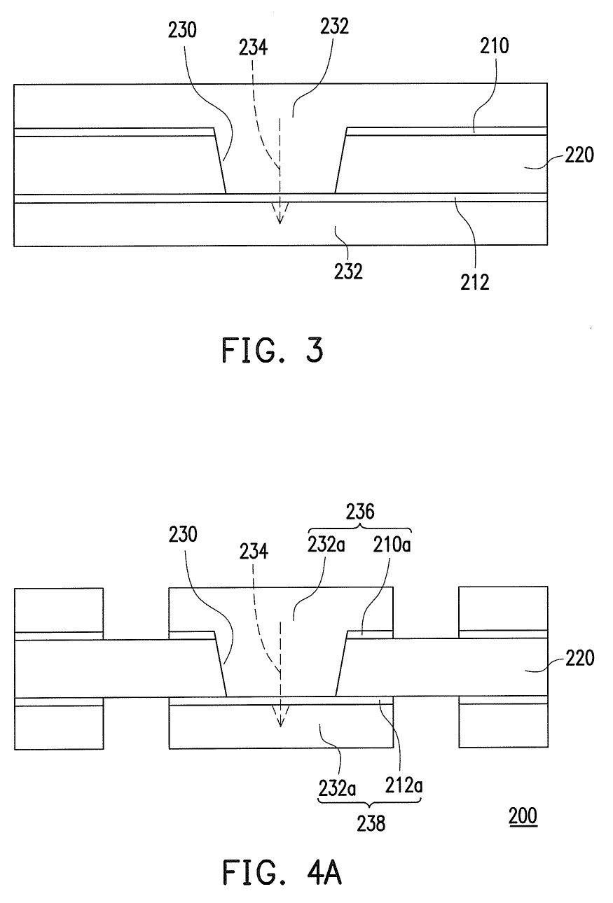

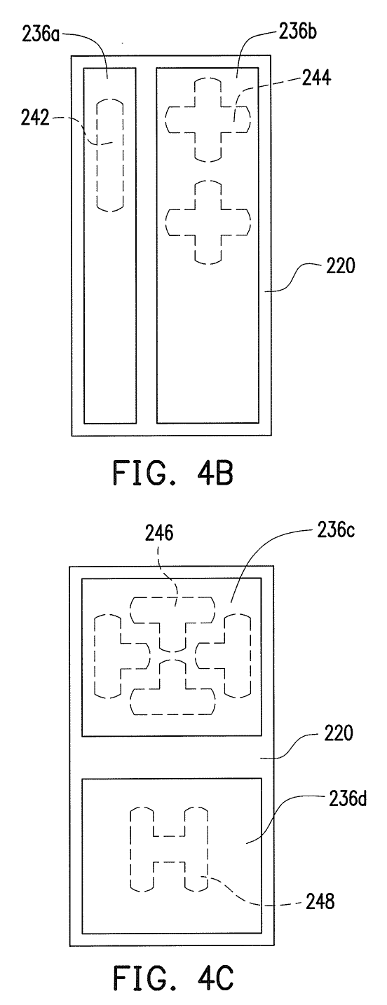

Next, in FIG. 3, a conductive material 232 is deposited in the non-cylinder via structure 230 by electroplating, so as to form a plurality of thermal channels 234 (in dotted lines) penetrating the insulating base material 220. The conductive material 232 is, for example, copper and can be entirely deposited above metal layers 210 and 212 and in the non-cylinder via structure 230 through electroplating. Thereafter, an etching process is performed, such that the remaining conductive material 232a and remaining metal layers 210a and 212a together form two metal patterned layers 236 and 238, as indicated in FIG. 4A. Accordingly, the upper and lower metal patterned layers 236 and 238 are conducted through the thermal channels 234 serving as heat dissipation paths of an electronic device.

FIGS. 4B and 4C are top views respectively illustrating a metal patterned layer depicted in FIG. 4A according to two embodiments of the present invention. In FIG. 4B, the metal patterned layer 236 is divided into two long and narrow electrode patterns 236a and 236b, and the bar-shaped pattern 242 and the cross-shaped patterns 244 in the non-cylinder via structures (in dotted lines) as depicted in FIG. 2B are respectively located in the electrode patterns 236a and 236b. Besides, in FIG. 4C, the metal patterned layer 236 is, for example, divided into two rectangular electrode patterns 236c and 236d, and the T-shaped patterns 246 and the H-shaped pattern 248 in the non-cylinder via structures (in dotted lines) as depicted in FIG. 2C are respectively located in the electrode patterns 236c and 236d. As such, the thermal enhanced substrate 200 in FIG. 4A can be used to support an electronic device (not shown), and the two electrode patterns can be electrically connected to the electronic device, respectively, such that the electronic device can emit light or transmit signals through inputting a working current thereto. For example, the electronic device is a light emitting device, a radio frequency (RF) device, a chip sacled package or a quad flat non-lead (QFN) chip package.

It can be deduced from the above that the thermal channels formed by depositing the conductive material in the non-cylinder via structure occupy a relatively large heat dissipation area and have favorable heat dissipating efficiency, such that heat generated by the electronic device can be rapidly dissipated through the non-cylinder thermal channels. Thereby, reduction of a working temperature of the electronic device can be expedited.

In light of the foregoing, the non-cylinder via structure and the thermal enhanced substrate having the same have favorable heat dissipation efficacy and are suitable for being used in package structures of high power electronic devices according to the present invention. As such, electronic devices can be applied to more products, such as back light modules in liquid crystal displays or white light illuminators. In addition, the thermal enhanced substrate can be applicable to a print circuit board, IC carrier or notebook PC.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-cylinder via structure, suitable for being used in a thermal enhanced substrate, the thermal enhance substrate supporting an electronic device and having at least a metal layer and a plurality of thermal channels, the thermal channels respectively comprising at least a trough pattern penetrating the thermal enhance substrate and a conductive material deposited in the trough pattern, wherein the trough pattern serves as the non-cylinder via structure having at least an elongated hole.

2. The non-cylinder via structure as claimed in claim 1, wherein the elongated hole is formed by performing an etching process with use of a plurality of continuous pulse waves.

3. The non-cylinder via structure as claimed in claim 1, wherein the elongated hole is formed by a plurality of cylinder vias arranged along a length direction of the elongated hole.

4. The non-cylinder via structure as claimed in claim 1, wherein two ends of the elongated hole along a length direction have a semicircular shape.

5. The non-cylinder via structure as claimed in claim 1, wherein the trough pattern has a bar shape, a cross shape, an X shape, an Y shape, an T shape, an L shape, an U shape, an H shape, a [symbol] shape, or a combination of at least two said shapes.

6. The non-cylinder via structure as claimed in claim 1, wherein the conductive material comprises copper.

7. A thermal enhanced substrate, suitable for supporting an electronic device, the thermal enhanced substrate comprising:
at least a metal layer, disposed on an insulating base material; and
a plurality of thermal channels, respectively comprising at least a trough pattern penetrating the insulating base material and a conductive material deposited in the at least a trough pattern,
wherein the trough pattern serves as a non-cylinder via structure having at least an elongated hole.

8. The thermal enhanced substrate as claimed in claim 7, wherein the elongated hole is formed by performing an etching process with use of a plurality of continuous pulse waves.

9. The thermal enhanced substrate as claimed in claim 7, wherein the elongated hole is formed by a plurality of cylinder vias arranged along a length direction of the elongated hole.

10. The thermal enhanced substrate as claimed in claim 7, wherein two ends of the elongated hole along a length direction have a semicircular shape.

11. The thermal enhanced substrate as claimed in claim 7, wherein the trough pattern has a bar shape, a cross shape, an X shape, an Y shape, an T shape, an L shape, an U shape, an H shape, a [symbol] shape, or a combination of at least two said shapes.

12. The thermal enhanced substrate as claimed in claim 7, wherein the conductive material comprises copper.
